(19) United States
(12) Patent Application Publication
(10) Pub. No.: US 2018/0143239 A1
(43) Pub. Date: May 24, 2018

(54) METHOD FOR ANALYSING A CABLE, INVOLVING A PROCESSING OPERATION AMPLIFYING THE SIGNATURE OF A SOFT FAULT

(71) Applicant: COMMISSARIAT A L'ENERGIE ATOMIQUE ET AUX ENERGIES ALTERNATIVES, PARIS (FR)

(72) Inventor: Soumaya SALLEM, Nogent sur Oise (FR)

(21) Appl. No.: 15/572,766

(22) PCT Filed: May 11, 2016
(86) PCT No.: PCT/EP2016/060489

§ 371 Date: Nov. 8, 2017

(30) Foreign Application Priority Data
May 22, 2015 (FR) 1554632

(51) Int. Cl. G01R 31/08; G01R 31/11; H04B 3/46; G01R 13/02

(52) U.S. Cl. CPC G01R 31/088; G01R 13/02; H04B 3/46; G01R 31/11

(57) ABSTRACT

A method for analyzing a cable into which a reference signal s(t) of bounded temporal support is injected comprises the following steps: acquiring a measurement signal r(t) characteristic of the measurement of the reflection of the reference signal s in the cable, identifying and selecting at least one point of the measurement signal r corresponding to when the signal crosses a zero value, generating, over a time interval centered around the at least one point with abscissa t₀, and a modified signal z(t) with the aid of the following relation z(t₀+t)=r(t₀+t)−r(t₀−t).

The invention relates to a reflectometry method and system for detecting and locating soft faults in a cable. The field of the invention is that of wired diagnostic systems based on the principle of reflectometry.

Cables are ubiquitous in all electrical systems, for power supply or information transmission. These cables are subject to the same constraints as the systems that they link and can be prone to failures. It is therefore necessary to be able to analyze their state and to afford information on the detection of faults, as well as their location and their type, in order to aid maintenance. Standard reflectometry schemes allow tests of this type.

Reflectometry schemes use a principle much like that of radar: an electrical signal, the probe signal, often of high frequency or wide band, is injected at one or more places into the cable to be tested. Said signal propagates in the cable or the network and returns part of its energy when it encounters an electrical discontinuity. An electrical discontinuity may result, for example, from a branch-off, from the end of the cable or from a fault or more generally from a break in the signal propagation conditions in the cable. It usually results from a fault which locally modifies the characteristic impedance of the cable by causing a discontinuity in its lineal parameters.

Analysis of the signals returned to the injection point makes it possible to deduce information therefrom about the presence and location of these discontinuities, therefore of possible faults. An analysis in the time or frequency domain is customarily carried out. These schemes are referred to by the acronyms TDR standing for the expression “Time Domain Reflectometry” and FDR standing for the expression “Frequency Domain Reflectometry”.

The invention applies to any type of electrical cable, particularly energy transmission cables or communication cables, in fixed or mobile installations. The cables concerned can be coaxial, bifilar, in parallel lines, in twisted pairs or of other types provided that it is possible to inject a reflectometry signal thereinto and to measure its reflection.

The known time domain reflectometry schemes are particularly suitable for the detection of hard faults in a cable, such as a short circuit or an open circuit or more generally an appreciable local modification of the impedance of the cable. The fault is detected by measuring the amplitude of the signal reflected on this fault, the amplitude being all the more significant, and therefore detectable, the harder the fault.

Conversely, a soft fault, for example resulting from a superficial degradation of the sheath of the cable of the insulator or of the conductor, gives rise to a low-amplitude spike on the reflected reflectometry signal and is consequently more difficult to detect through conventional time-based schemes.

Detection and location of a soft fault on a cable is a significant problem for the industrial world since in general a fault appears firstly as a superficial fault but may, over time, evolve into a fault having greater impact. For this reason in particular, it is useful to be able to detect the appearance of a fault right from its appearance and at a juncture at which its impact is superficial so as to anticipate its evolution into a more significant fault.

The known schemes allowing the identification of soft faults on a cable are usually time-frequency reflectometry schemes. These schemes have been developed so as to enable reflected signals of low amplitude to be better revealed.

In particular the scheme “Joint Time-Frequency Domain Reflectometry” described in the document Y. J. Shin. “Theory and Application of Time-Frequency Analysis to Transient Phenomena”, in Electric Power and Other Physical Systems. PhD thesis, University of Texas, 2004 is known, which proposes the use of the Wigner-Ville frequency transform. This scheme allows better discrimination of the signal reflections on soft faults with good temporal and frequency resolution. However, it exhibits the dual drawback of being complex to implement in an embedded system and leads to problems of false detection due to the existence of cross terms in the aforementioned transform.

The Applicant's French patent application published under the number FR 2981752 proposes an enhancement of the time-frequency scheme described in the aforesaid document by Y. J. Shin, which makes it possible to eliminate the influence of the cross terms and to dispense with the problems of false detection.

However, this scheme still presents the drawback of significant complexity of implementation for handheld equipment.

The invention proposes a scheme for analyzing a cable with a view to the detection of soft faults which remedies the limitations of the prior art solutions. The invention allows the signature of soft faults to be amplified without also amplifying the noise. To obtain this result, the scheme is based on an identification of the zones of the signal corresponding to signatures of potential faults and then to the application of a particular signal processing function to these zones so as to amplify the signatures of low amplitude without amplifying the noise.

The proposed scheme is scarcely complex since it calls upon elementary operations of the addition, subtraction or multiplication type.

The subject of the invention is a method for analyzing a cable into which a reference signal s(t) of bounded temporal support is injected, characterized in that it comprises the following steps:
Acquiring a measurement signal r(t) characteristic of the measurement of the reflection of said reference signal s in the cable,
Identifying and selecting at least one point of said measurement signal r corresponding to when the signal crosses a zero value and whose abscissa is denoted t₀,
Generating, over a time interval centered around said at least one point with abscissa t₀, at least one modified signal z(t) with the aid of the following relation z(t₀+t)=r(t₀+t)−r(t₀−t),
Identifying at least one possible fault on the cable on the basis of the analysis of said at least one modified signal z(t).

According to a particular variant, the method according to the invention furthermore comprises a step of dividing said modified signal by an amplification factor C dependent on the integration of said measurement signal r(t) over a half of said time interval.

According to a particular aspect of the invention, the amplification factor is equal to the absolute value of the average or of the energy of said measurement signal r(t) over a half of said time interval.

According to a particular variant, the method according to the invention furthermore comprises a step of sorting the points of said measurement signal r(t) corresponding to when the signal crosses a zero value, the selection of a point being carried out by comparing a value representative of the energy of said measurement signal r, calculated at least over a time interval taken from among a first time interval whose upper bound is equal to the abscissa t₀ of said point or a second time interval whose lower bound is equal to the abscissa t₀ of said point, with a threshold configured at least as a function of the characteristics of the signal.

According to a particular aspect of the invention, the selection of a point is carried out by comparing a value representative of the energy of said measurement signal r(t), calculated respectively over said first time interval and over said second time interval, with a threshold configured at least as a function of the characteristics of the signal.

According to a particular aspect of the invention, said threshold is configured as a function of the signal-to-noise ratio.

According to a particular aspect of the invention, the reference signal s(t) injected into the cable is an impulse signal.

According to a particular aspect of the invention, the duration of the time interval centered around said point with abscissa t₀ is substantially equal to twice the pulse width of the reference signal s.

According to a particular variant, the method according to the invention furthermore comprises a step of searching for at least one extremum of the modified signal z(t) indicating the presence of a fault on the cable.

The subject of the invention is also a device for the analysis of a cable comprising means adapted to implement the analysis method according to the invention.

The subject of the invention is also a device for the analysis of a cable comprising an apparatus for measuring, at a point of the cable, a signal reflected in the cable and a calculator configured to execute the analysis method according to the invention.

The subject of the invention is also a reflectometry system comprising a device for the analysis of a cable according to the invention.

According to a particular variant, the reflectometry system according to the invention furthermore comprises a device for injecting, at a point of the cable, a reference signal.

The subject of the invention is also a computer program comprising instructions for the execution of the method for analyzing a cable according to the invention, when the program is executed by a processor.

The subject of the invention is also a recording medium readable by a processor on which is recorded a program comprising instructions for the execution of the method for analyzing a cable according to the invention, when the program is executed by a processor.

Other characteristics and advantages of the present invention will become more clearly apparent on reading the description which follows in relation to the appended drawings which represent:

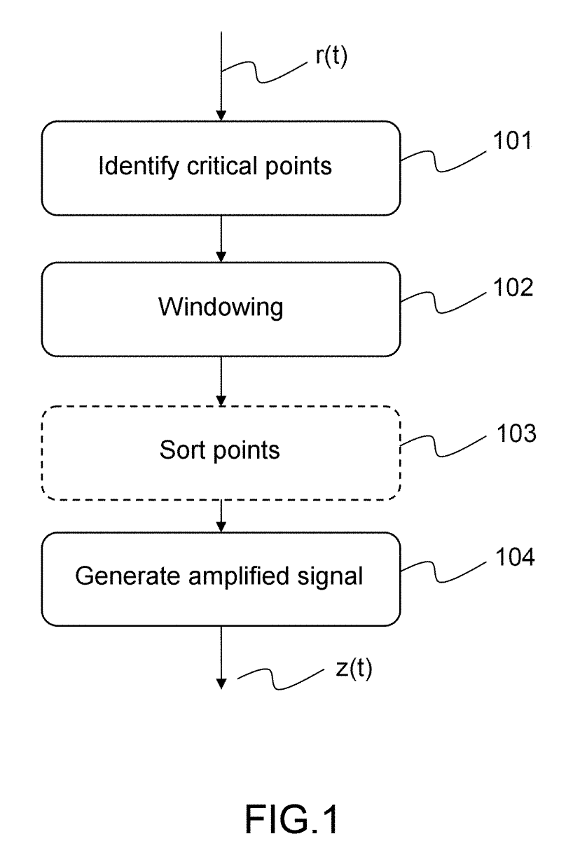

FIG. 1, a flowchart illustrating the steps of the analysis method according to the invention,

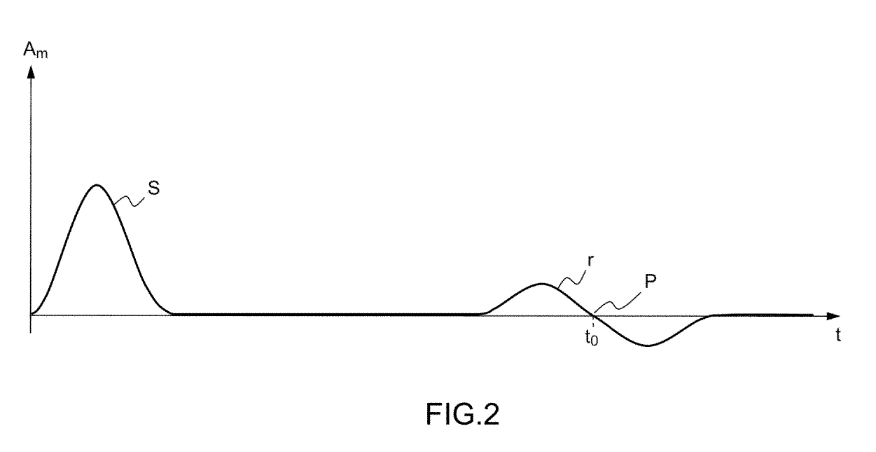

FIG. 2, a time-domain reflectogram representing an exemplary reference signal s and an exemplary signature r of the signal reflected on a soft fault,

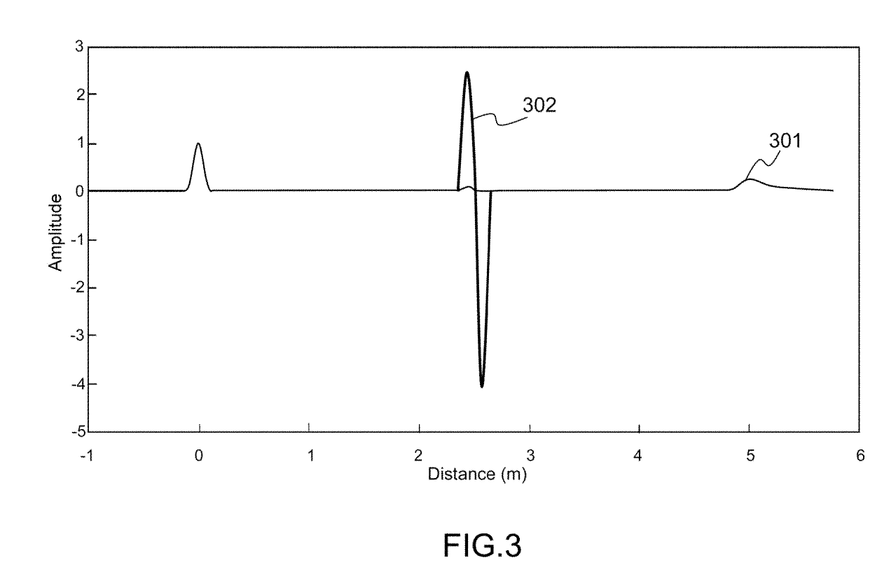

FIG. 3, an exemplary comparison between a time-domain reflectogram obtained with and without application of the invention.

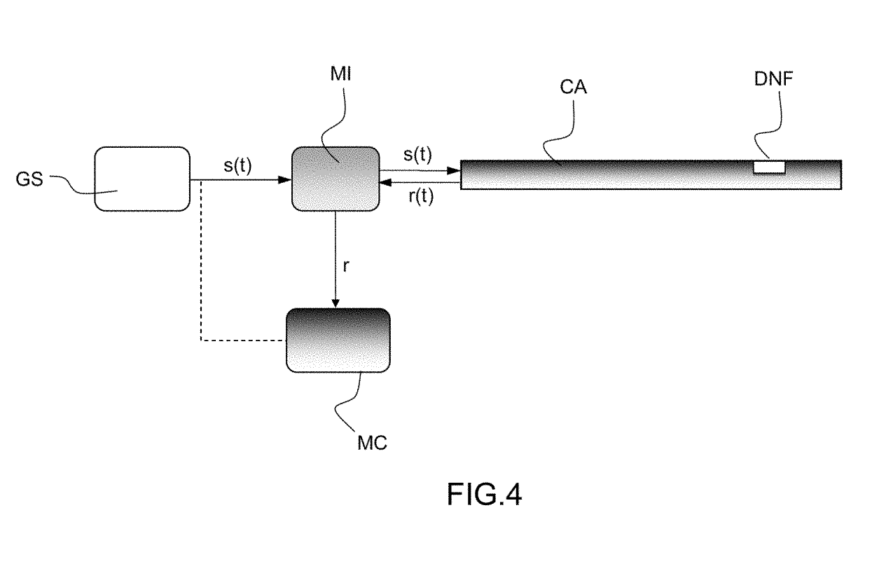

FIG. 4, a diagram of an exemplary embodiment of an analysis device according to the invention

FIG. 1 details on a flowchart the implementation steps of the invention according to an exemplary embodiment.

The invention consists of the application of a signal processing method to a reflectometry measurement. Such a measurement can be obtained by injecting a reference signal s into a cable at an injection point and then by measuring the reflection of this signal, at the same injection point or at a different measurement point. The signal s propagating in the cable encounters impedance discontinuities which give rise to reflections. The invention can therefore be applied directly to a measurement r of the reflected signal when the reference signal s injected into the cable has bounded temporal support and is of the impulse signal type. For example, the reference signal s may consist of a Gaussian pulse but also a pulse of the triangular or square-wave type.

The invention is not limited, however, to signals of this type and is applicable more generally to any type of reference signals used in reflectometry. For example, the reference signal s can also consist of a baseband digital sequence of the STDR type, the acronym standing for “Sequence time domain reflectometry”, or of a spread-spectrum signal of the SSTDR type, the acronym standing for “Spread Spectrum time domain reflectometry”. In both these latter cases, however, the invention applies not directly to the measurement r of the reflected signal but to this measurement intercorrelated with the injected signal s. This prior processing is necessary in order to reduce to a signal of impulse type for which the signatures of the reflections on impedance discontinuities exhibit only a single zero-crossing. This point will be explained in greater detail hereinafter.

Generally, the scheme according to the invention can include a step of injecting a reference signal into the cable to be tested and then a step of measuring the reflected signal. But the invention can also be applied directly to a reflection measurement which has been carried out beforehand and then recorded on a saving medium. The invention can also be applied to a measurement signal to which a preprocessing has been applied, for example to perform a first denoising step or to recenter the average of the signal on a zero value. The person skilled in the art will be able without difficulty to extend the application of the invention beyond the specific examples described for any type of signals characteristic of a time-domain reflectometry measurement.

The aim of the signal processing method according to the invention is to selectively amplify the signatures of soft faults, that is to say of faults of low amplitude, without amplifying artifacts due to noise and also without amplifying the signatures of hard faults.

The term signature is used here to refer to the portion of the measurement of the reflected signal which corresponds to the reflection of the signal on an impedance discontinuity.

FIG. 2 illustrates an exemplary time-domain reflectogram on which is represented the reference signal s, injected into the cable, which exhibits a Gaussian pulse shape. On the same reflectogram is represented the signature r of the reflection of this signal on a soft fault. This signature r consists of the superposition of a pulse of positive amplitude and of the same pulse of negative amplitude. This particular shape is due to the fact that the incident signal is reflected a first time on the interface corresponding to the entry point of the soft fault, and then a second time on the interface corresponding to the exit point of the soft fault, assuming that the fault exhibits a non-zero length on the cable. This principle is well known to the field of time-domain reflectometry systems applied to the diagnosis of transmission lines or cables.

In the example of FIG. 2, the amplitude of the signature r of the soft fault is intentionally amplified for readability reasons. In reality and according to the nature of the fault and its significance, the amplitude of the signature r may be very low with respect to the amplitude of the injected signal. Consequently, its detection and its location may pose a problem in particular for very superficial faults of the cable insulator scuffing type.

According to a first step 101 of the method according to the invention, a search is undertaken for critical points in the measurement signal r, these critical points corresponding to zero-crossings of the signal.

In the example of FIG. 2, a critical point P such as this, with temporal abscissa t₀, has been identified.

On completion of the first step 101, a set of critical points is obtained together with their respective temporal abscissae.

To improve the precision of location of the critical points, a prior preprocessing can be applied to correct the global amplitude of the signal using a factor making it possible to obtain a zero average of the signal, over the signal portion comprising solely the signatures of faults.

An aim of the first step 101 is to identify the zero-crossings of the signal which correspond a priori to reflections of the signal on impedance discontinuities.

In a step 102, for each critical point identified, a portion of the signal comprising the critical point is selected. The signal portion is limited to a time interval centered on the critical point and of predetermined duration. Advantageously, the duration of the time interval is at least equal to twice the duration of the pulse of the reference signal s. The signal portion selected must encompass the fault signature associated with the critical point.

To improve the precision of the first step 101 of selecting the critical points, it is possible to add a step 103 of sorting the points selected in step 101. The aim of this step is to eliminate the critical points which correspond to measurement noise rather than to signatures of faults.

A possible implementation of step 103 of sorting the critical points consists in calculating, over the duration of the time interval selected in step 102, the average of the signal in the temporal sub-interval of the times that are less than the abscissa t₀ of the critical point or the average of the signal in the temporal sub-interval of the times that are greater than the abscissa t₀ of the critical point or both at once. The absolute value of one or the other (or of both) average(s) is thereafter compared with a comparison threshold configured as a function of characteristics of the signal and/or of the envisaged application. For example, the threshold may depend on the signal-to-noise ratio. If the absolute value of the average (or if the absolute value of each average) exceeds the comparison threshold, it is deduced therefrom that the identified signature does indeed correspond to a fault. In the converse case, it is deduced therefrom that the identified critical point corresponds to a measurement artifact or more generally to noise. The comparison threshold is fixed at a value which depends on the parameters of the injected signal (its amplitude in particular) and other parameters related to the characteristics of the cable (its attenuation for example) or to the characteristics of the measurement apparatuses used. The threshold value used must make it possible to reject the critical points corresponding to noise and preserve the critical points corresponding to faults. This value can in particular be adjusted as a function of the minimum resolution of the amplitude of a fault that it is desired to be able to detect. The person skilled in the art will be able, with the aid of routine tests, to adjust the value of the comparison threshold as a function of the envisaged system.

In another step 104, for each selected fault signature, a modified signal z(t) is generated, for which the soft faults are amplified.

According to a first embodiment, the modified signal can be calculated with the aid of the following relation:

z(t₀+t)=r(t₀+t)−r(t₀−t) (1)

for t varying over the time interval selected in step 102. For example if the duration of the time interval is equal to T, t varies between −T/2 and T/2.

Relation (1) linking z(t) and r(t) can also be written in the form:

z(t)=r(t)−r(2t₀−t) for t varying between to −T/2 and t₀+T/2

The signal modified with the aid of relation (1) makes it possible on the one hand to amplify the amplitude of a fault when its signature is of the type of that described in FIG. 2, that is to say the superposition of a positive pulse and of a negative pulse with a point of symmetry at the point with abscissa t₀. Moreover, relation (1) also makes it possible to dispense with the contribution of the noise if it is assumed that the noise is distributed randomly in the interval.

According to a second embodiment, the signal z(t) calculated with the aid of relation (1) can furthermore be normalized or divided by an additional amplification factor C calculated on the basis of the integral of the reflected signal r over a duration equal to the lower or upper half of the interval.

$$C = \frac{1}{\frac{T}{2}} \vert {\int }_{t 0 - \frac{T}{2}}^{t 0} r ( {t}^{′} ) {dt}^{′} \vert = \frac{1}{\frac{T}{2}} \vert {\int }_{t 0}^{t 0 + \frac{T}{2}} r ( {t}^{′} ) {dt}^{′} \vert \qquad ( 2 )$$

The normalization term C corresponds to the average of the reflected signal r(t) over a duration T/2 or else to its energy. Alternatively, the term C can be replaced by the reflected-signal power calculated over the same duration.

The signal modified in step 104 is thereafter given by the relation z(t)=z(t)/C.

This step of additional normalization allows the soft faults, that is to say faults of low amplitude, to be amplified more strongly without amplifying the hard faults and also without amplifying the impedance mismatches at the input of the cable or at its termination.

The modified signals z(t) generated for each time interval and associated with a fault make it possible to reconstruct a complete reflectogram by replacing solely, in the measurement r of the reflected signal, the portions of signals associated with the time intervals selected with the modified signals z(t).

On the basis of the modified reflectogram obtained, it is thereafter possible to characterize a fault, in particular a soft fault, by known signal processing techniques which are not described here. In summary, it is made possible to locate faults by searching for an extremum in the reflectogram. Measuring the amplitude of the signatures of the located faults makes it possible to estimate the characteristic impedance of the faults.

The method according to the invention allows the signatures of soft faults to be selectively amplified without amplifying the noise and by way of a processing relying on simple operations. The invention is thus not very complex to execute and is compatible with implementations on embedded diagnostic equipment.

FIG. 3 represents, on the same timechart, the measurement r 301 of the signal reflected in a cable exhibiting a soft fault at a distance of about 2.5 m from the end of the cable and the amplified signal 302 according to the invention.

FIG. 4 shows diagrammatically, on a schematic, an exemplary reflectometry system able to implement the method according to the invention.

A reflectometry system, or reflectometer, comprises at least one signal generator GS, for generating a test signal s and injecting it into the cable to be analyzed CA which comprises a soft fault DNF, an item of measurement equipment MI for measuring the reflected signal r in the cable CA and an electronic component MC of integrated circuit type, such as a programmable logic circuit, for example of FPGA type or a micro-controller, for example a digital signal processor, which receives the measurement of the reflected signal r(t) and is configured to execute the method according to the invention, described in FIG. 1, so as to produce a modified measurement signal z(t) in which the soft faults are amplified.

The component MC can furthermore execute other additional processings on the modified signal z(t) with a view to determining the site and the physical characteristics of faults impacting the cable CA, in particular of soft faults.

According to a particular embodiment, the injected test signal s can also be provided to the component MC when the processings carried out require the knowledge of the injected signal, in particular when they include a step of intercorrelation between the test signal s and the reflected signal r.

The injection of the signal into the cable and the measurement of the reflected signal can be carried out by one and the same component but also by two distinct components, in particular when the injection point and the measurement point are dissociated.

The system described in FIG. 4 can be implemented by an electronic board on which the various components are disposed. The board can be connected to the cable by a coupler.

Furthermore, a processing unit, of computer or personal digital assistant or other equivalent electronic or computing device type can be used to drive the reflectometry device and display the results of the calculations performed by the component MC on a man-machine interface.

The method according to the invention can be implemented on the component MC on the basis of hardware and/or software elements.

The method according to the invention can be implemented directly by an embedded processor or in a specific device. The processor can be a generic processor, a specific processor, an Application-Specific Integrated circuit (ASIC) or a Field-Programmable Gate Array (FPGA). The device according to the invention can use one or more dedicated electronic circuits or a general-purpose circuit. The technique of the invention can be carried out on a reprogrammable calculation machine (a processor or a microcontroller for example) executing a program comprising a sequence of instructions, or on a dedicated calculation machine (for example a set of logic gates such as an FPGA or an ASIC, or any other hardware module).

The method according to the invention can also be implemented exclusively in the guise of a computer program, the method then being applied to a reflectometry measurement r acquired previously with the aid of a standard reflectometry device. In such a case, the invention can be implemented in the guise of a computer program comprising instructions for its execution. The computer program can be recorded on a recording medium readable by a processor.

The reference to a computer program which, when it is executed, performs any one of the previously described functions, is not limited to an application program executing on a single host computer. On the contrary, the terms computer program and software are used here in a general sense to refer to any type of computer code (for example, application software, microsoftware, microcode, or any other form of computer instruction) which can be used to program one or more processors to implement aspects of the techniques described here. The computing means or resources can in particular be dispersed (“Cloud computing”), optionally according to peer-to-peer technologies. The software code can be executed on any appropriate processor (for example, a microprocessor) or processor core or a set of processors, be they provided in a single calculation device or distributed between several calculation devices (for example such as may optionally be accessible in the environment of the device). The executable code of each program allowing the programmable device to implement the processes according to the invention, can be stored, for example, in the hard disk or in read-only memory. Generally, the program or programs will be able to be loaded into one of the storage means of the device before being executed. The central unit can control and direct the execution of the instructions or portions of software code of the program or programs according to the invention, which instructions are stored in the hard disk or in the read-only memory or else in the other aforementioned storage elements.

The invention is applied in respect of the diagnosis of superficial faults on any type of transmission line or cable. In particular the invention applies to the monitoring of junctions between two transmission lines in networks of cables.

The invention also applies to the monitoring of the state of health of structures other than electrical cables. Such structures can include elements of bridges or of walls for the building and civil construction industry or else an element of an airplane wing, a fuselage or else a blade for the aeronautical industry. To monitor the localized deterioration of a structure, one principle consists in positioning one or more transmission lines on the surface of the structure and in applying a reflectometry-based processing to each of these lines.

1. A method for analyzing a cable into which a reference signal s(t) having a bounded temporal support is injected, the method comprising the steps of:
acquiring a measurement signal r(t) characteristic of the measurement of the reflection of said reference signal s in the cable,
identifying and selecting at least one point of said measurement signal r corresponding to when the signal crosses a zero value and whose abscissa is denoted t₀,
generating, over a time interval centered around said at least one point with abscissa t₀, at least one modified signal z(t) with the aid of the following relation z(t₀+t)=r(t₀+t)−r(t₀−t),
identifying at least one possible fault on the cable on the basis of the analysis of said at least one modified signal z(t).

2. The method for analyzing a cable of claim 1, further comprising dividing said modified signal by an amplification factor C dependent on the integration of said measurement signal r(t) over a half of said time interval.

3. The method for analyzing a cable of claim 2, wherein the amplification factor is equal to the absolute value of the average or of the energy of said measurement signal r(t) over a half of said time interval.

4. The method for analyzing a cable of claim 1, further comprising sorting the points of said measurement signal r(t) corresponding to when the signal crosses a zero value, the selection of a point being carried out by comparing a value representative of the energy of said measurement signal r, calculated at least over a time interval taken from among a first time interval whose upper bound is equal to the abscissa t₀ of said point or a second time interval whose lower bound is equal to the abscissa t₀ of said point, with a threshold configured at least as a function of the characteristics of the signal.

5. The method for analyzing a cable of claim 4, wherein the selection of a point is carried out by comparing a value representative of the energy of said measurement signal r(t), calculated respectively over said first time interval and over said second time interval, with a threshold configured at least as a function of the characteristics of the signal.

6. The method for analyzing a cable of claim 4, wherein said threshold is configured as a function of the signal-to-noise ratio.

7. The method for analyzing a cable claim 1, wherein the reference signal s(t) injected into the cable is an impulse signal.

8. The method for analyzing a cable of claim 7, wherein the duration of the time interval centered around said point with abscissa t₀ is substantially equal to twice the pulse width of the reference signal s.

9. The method for analyzing a cable of claim 1, wherein said method furthermore comprises a step of searching for at least one extremum of the modified signal z(t) indicating the presence of a fault on the cable.

10. (canceled)

11. A device for the analysis of a cable comprising an apparatus for measuring, at a point of the cable, a signal reflected in the cable and a calculator configured to execute a method for analyzing a cable into which a reference signal s(t) having a bounded temporal support is injected, the method comprising the steps of:
acquiring a measurement signal r(t) characteristic of the measurement of the reflection of said reference signal s in the cable,
identifying and selecting at least one point of said measurement signal r corresponding to when the signal crosses a zero value and whose abscissa is denoted t₀,
generating, over a time interval centered around said at least one point with abscissa t₀, at least one modified signal z(t) with the aid of the following relation z(t₀+t)=r(t₀+t)−r(t₀−t),
identifying at least one possible fault on the cable on the basis of the analysis of said at least one modified signal z(t).

12. A reflectometry system comprising a device for the analysis of a cable according to claim 11.

13. The reflectometry system of claim 12, further comprising a device for injecting, at a point of the cable, a reference signal.

14. A computer program comprising instructions stored on a tangible non-transitory storage medium for executing on a processor a method for analyzing a cable into which a reference signal s(t) having a bounded temporal support is injected, the method comprising the steps of:
acquiring a measurement signal r(t) characteristic of the measurement of the reflection of said reference signal s in the cable,
identifying and selecting at least one point of said measurement signal r corresponding to when the signal crosses a zero value and whose abscissa is denoted t₀,
generating, over a time interval centered around said at least one point with abscissa t₀, at least one modified signal z(t) with the aid of the following relation z(t₀+t)=r(t₀+t)−r(t₀−t),
identifying at least one possible fault on the cable on the basis of the analysis of said at least one modified signal z(t).

15. A tangible non-transitory processor-readable recording medium on which is recorded a program comprising instructions for executing a method for analyzing a cable into which a reference signal s(t) having a bounded temporal support is injected, the method comprising the steps of:
acquiring a measurement signal r(t) characteristic of the measurement of the reflection of said reference signal s in the cable,
identifying and selecting at least one point of said measurement signal r corresponding to when the signal crosses a zero value and whose abscissa is denoted t₀,
generating, over a time interval centered around said at least one point with abscissa t₀, at least one modified signal z(t) with the aid of the following relation z(t₀+t)=r(t₀+t)−r(t₀−t),
identifying at least one possible fault on the cable on the basis of the analysis of said at least one modified signal z(t).
